(19) United States
(12) Patent Application Publication
(10) Pub. No.: US 2017/0330734 A1
(43) Pub. Date: Nov. 16, 2017

(54) PLASMA PROCESSING APPARATUS

(71) Applicant: SAMSUNG ELECTRONICS CO., LTD., Suwon-si (KR)

(72) Inventors: Jun-soo LEE, Seoul (KR); Je-hun WOO, Suwon-si (KR); Sang-min JEONG, Seoul (KR); Eung-su KIM, Seoul (KR); Hak-young KIM, Bucheon-si (KR)

(21) Appl. No.: 15/384,354

(22) Filed: Dec. 20, 2016

(30) Foreign Application Priority Data
May 12, 2016 (KR) 10-2016-0058189

(51) Int. Cl. H01J 37/32

(52) U.S. Cl. CPC H01J 37/32724; H01J 37/3299; H01J 37/3244; H01J 37/32642; H01J 2237/334

(57) ABSTRACT

A plasma processing apparatus includes a process chamber providing a space for plasma processing, a lower electrode that is in the process chamber, a surface of the lower electrode being for mounting a wafer thereon, an upper electrode that is in the process chamber and faces the lower electrode, a gas supplier configured to supply process gas between the upper electrode and the lower electrode, a focus ring arranged on the lower electrode to surround an edge of the wafer mounted on the lower electrode, an edge ring arranged below the focus ring and including first bodies that are separate from each other with a space therebetween, a plurality of heaters installed in the first bodies, and a heater controller configured to separately control driving of each of the heaters.

### CROSS-REFERENCE TO RELATED APPLICATION

Korean Patent Application No. 10-2016-0058189, filed on May 12, 2016, in the Korean Intellectual Property Office, and entitled: “Plasma Processing Apparatus,” is incorporated by reference herein in its entirety.

### BACKGROUND

### 1. Field

Embodiments relate to a plasma processing apparatus.

### 2. Description of the Related Art

Generally, a semiconductor device is manufactured by performing a plurality of unit processes that include a deposition process and an etching process on a thin film. The etching process may be performed in a semiconductor manufacture facility in which a plasma reaction is induced.

### SUMMARY

Embodiments are directed to a plasma processing apparatus, including a process chamber providing a space for plasma processing, a lower electrode that is in the process chamber, a surface of the lower electrode being for mounting a wafer thereon, an upper electrode that is in the process chamber and faces the lower electrode, a gas supplier configured to supply process gas between the upper electrode and the lower electrode, a focus ring arranged on the lower electrode to surround an edge of the wafer mounted on the lower electrode, an edge ring arranged below the focus ring and including first bodies that are separate from each other with a space therebetween, a plurality of heaters installed in the first bodies, and a heater controller configured to separately control driving of each of the heaters.

Embodiments are also directed to a plasma processing apparatus, including a process chamber providing a space for plasma processing, a lower electrode that is in the process chamber, a surface of the lower electrode being for mounting a wafer thereon, an upper electrode that is in the process chamber and faces the lower electrode, a gas supplier configured to supply processing gas to a processing space between the upper electrode and the lower electrode, a focus ring arranged on the lower electrode to surround an edge of the wafer mounted on the lower electrode, an edge ring arranged below the focus ring and including first bodies that are separate from each other with a space therebetween, a plurality of heaters installed in the first bodies, a heater controller configured to separately control driving of each of the heaters, and a test apparatus configured to receive the wafer from the process chamber and test the wafer after an etching process is performed on the wafer, and apply a first feedback signal to the heater controller if a result of the testing shows that an asymmetric distribution fault has occurred in the tested wafer. The heater controller may drive the heaters so that some of the first bodies are heated according to the first feedback signal.

Embodiments are also directed to an edge ring for a plasma processing apparatus, the edge ring including a plurality of arc-shaped sections, the arc-shaped sections being provided in a number sufficient to define a circle, and electrically-driven thermal control elements contacting the arc-shaped sections, each arc-shaped section having at least one thermal control element in contact therewith.

### BRIEF DESCRIPTION OF THE DRAWINGS

Features will become apparent to those of skill in the art by describing in detail exemplary embodiments with reference to the attached drawings in which:

FIG. 1 illustrates a cross-sectional view of a plasma processing apparatus according to an example embodiment;

FIG. 2 illustrates an exploded perspective view of a focus ring and an edge ring shown in FIG. 1;

FIG. 3 illustrates a schematic diagram of first bodies of an edge ring, included in the plasma processing apparatus, and a heater controller configured to control driving of heaters included in the first bodies according to an example embodiment;

FIG. 4 illustrates a schematic diagram of first bodies of an edge ring, included in the plasma processing apparatus, and a heater controller configured to control driving of heaters included in the first bodies according to an example embodiment;

FIG. 5 illustrates a schematic cross-sectional view of a heater included in the plasma processing apparatus according to an example embodiment;

FIG. 6 illustrates a schematic plan view of an edge ring included in the plasma processing apparatus according to an example embodiment;

FIG. 7 illustrates a plan view of a focus ring and an edge ring included in the plasma processing apparatus according to an example embodiment;

FIG. 8 illustrates a plan view of a focus ring and an edge ring included in the plasma processing apparatus according to an example embodiment;

FIG. 9 illustrates a schematic block diagram of a plasma processing apparatus according to an example embodiment; and

FIGS. 10A and 10B illustrate schematic distribution maps of a wafer which is generated by using a test apparatus shown in FIG. 9.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art. In the drawing figures, the dimensions of layers and regions may be exaggerated for clarity of illustration. Like reference numerals refer to like elements throughout.

As used herein, the term “and/or” includes any and all combinations of one or more of the associated listed items. Expressions such as “at least one of,” when preceding a list of elements, modify the entire list of elements and do not modify the individual elements of the list.

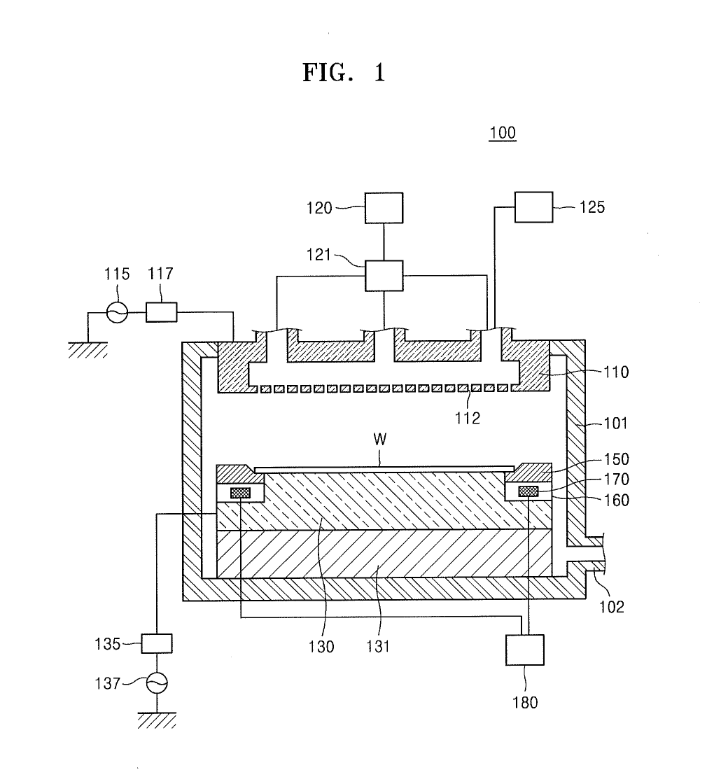

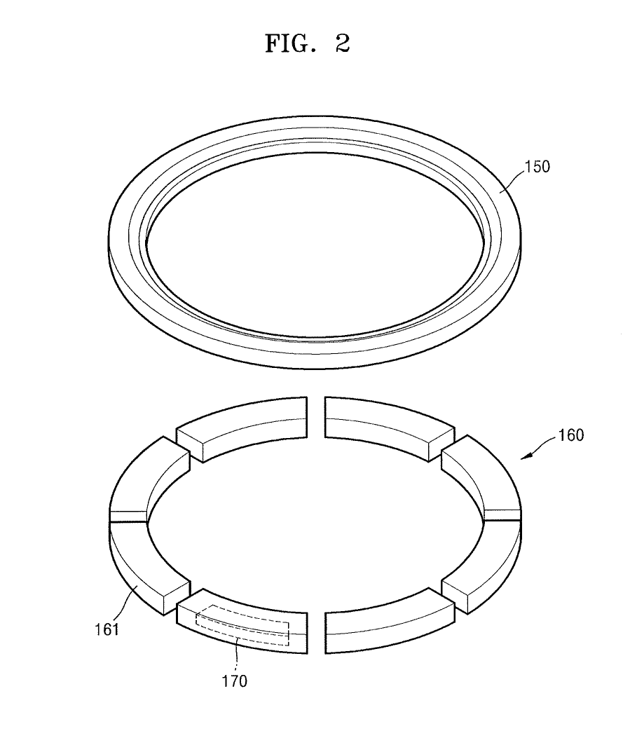

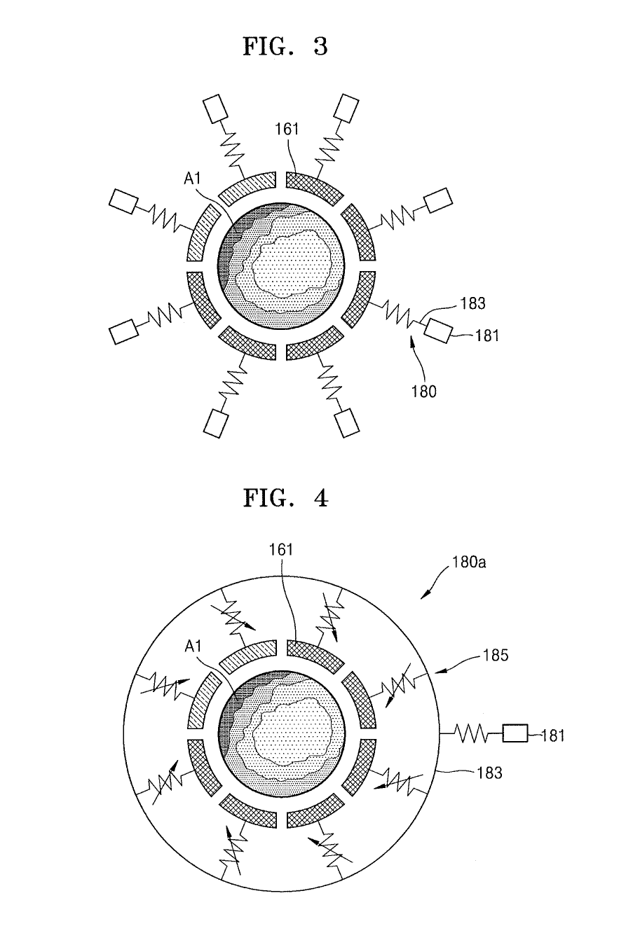

FIG. 1 is a cross-sectional view of a plasma processing apparatus 100 according to an example embodiment. FIG. 2 is an exploded perspective view of a focus ring 150 and an edge ring 160 shown in FIG. 1. FIG. 3 is a schematic diagram of first bodies 161 of the edge ring 160, included in the plasma processing apparatus 100, and a heater controller 180 configured to control driving of heaters 170 included in the first bodies 161 according to an example embodiment.

Referring to FIGS. 1 through 3, the plasma processing apparatus 100 may include a process chamber 101, an upper electrode 110, a gas supplier 120, a gas splitter 121, an edge tuning gas supplier 125, a lower electrode 130, the focus ring 150, the edge ring 160, the heaters 170, and the heater controller 180.

The process chamber 101 may provide an inner space isolated from the outside, and the inner space may be provided as a processing space for processing a wafer W by using plasma. The process chamber 101 may include an etching chamber in which the wafer W or a thin film on the wafer W is etched according to a plasma reaction. An etching process of patterning the wafer W or at least one thin film selected from among a silicon film, an oxidation film, a nitride film, and a metal film may be performed in the process chamber 101. The process chamber 101 may be connected to a transfer chamber or a loadlock chamber for relieving a vacuum condition.

According to one or more embodiments, the process chamber 101 may be formed of metal, an insulation body, or a combination thereof. According to another embodiment, an inside of the process chamber 101 may be coated with an insulation body. The process chamber 101 may have, for example, a rectangular or cylinder shape.

An entrance/exit gate may be provided at a side of the process chamber 101. Wafers W enter or exit from the process chamber 101 via the entrance/exit gate. Additionally, the process chamber 101 may further include an exhaust duct 102 configured to exhaust reaction gas or a reaction by-product. The exhaust duct 102 may be connected to a vacuum pump. A pressure control valve, a flow control valve, or the like may be installed in the exhaust duct 102.

The upper electrode 110 may be installed in an inner space of the process chamber 101. The upper electrode 110 may receive supply of process gas from the gas supplier 120, and provide a path via which the process gas may move into the upper electrode 110. After the process gas is supplied to the upper electrode 110 via the gas supplier 120, the process gas may move via the path provided in the upper electrode 110, and then be supplied to the wafer W seated on the lower electrode 130 via gas spraying holes 112 formed in a lower surface of the upper electrode 110.

A first high-frequency power source 115 may be electrically connected to the upper electrode 110 via a first impedance matcher 117. The first high-frequency power source 115 may output a high frequency (of, for example, 60 MHz) which is appropriate for generating plasma, by discharging the process gas from the process chamber 101. The first impedance matcher 117 may match an impedance at the first high-frequency power source 115 with an impedance at the process chamber 101.

The lower electrode 130 is installed in an inner space of the process chamber 101, and may face the upper electrode 110. The lower electrode 130 may include, for example, an electrostatic chuck (ESC) for fixing the wafer W by using static electricity, a chuck for fixing the wafer W by using a mechanical clamping method, or a vacuum chuck for adsorbing and supporting the wafer W by using vacuum pressure. The lower electrode 130 may include a heating element configured to heat the wafer W to a process temperature. Additionally, the lower electrode 130 may be arranged on a support member 131.

A second high-frequency power source 135 may be electrically connected to the lower electrode 130 via a second impedance matcher 137. The second high-frequency power source 135 may output power for bias, and output a high frequency (of, for example, 2 MHz) which is appropriate for controlling ion energy input to the wafer W. The second impedance matcher 137 may match an impedance at the second high-frequency power source 135 with an impedance at the process chamber 101.

As the process gas spreads to a space between the upper electrode 110 and the lower electrode 130 and, at the same time, high-frequency power for discharging the process gas is applied to the upper electrode 110 and the lower electrode 130, the process gas is converted into a state of plasma, and the plasma contacts a surface of the wafer W, and thus a physical or chemical reaction occurs. A process of processing the wafer W such as annealing, etching, deposition, washing, or the like may be performed by using the physical or chemical reaction.

The gas splitter 121 may be installed on a gas supply line via which the process gas moves between the gas supplier 120 and the upper electrode 110. The gas splitter 121 may distribute flow of the process gas supplied to the center of the wafer W and the edge of the wafer W at a certain ratio.

For example, the gas splitter 121 may increase flow of the process gas supplied toward the edge of the wafer W, which may help reduce or eliminate a distribution fault (where a critical dimension (CD) at an edge of the wafer W is higher than a CD at the center of the wafer W). As the gas splitter 121 increases flow of the process gas supplied toward the edge of the wafer W, the density of plasma at an edge of a processing space increases. Resultantly, the density of the plasma may become uniform in the processing space, and the distribution fault in an etching process may be resolved.

The edge tuning gas supplier 125 may supply edge tuning gas toward the edge of the wafer W. For example, the edge tuning gas supplier 125 may supply edge tuning gas toward the edge of the wafer W via the gas spraying holes 112 arranged at an edge of the upper electrode 110. The edge tuning gas may be identical to or different from the process gas supplied via the gas supplier 120.

For example, the edge tuning gas supplier 125 may supply edge tuning gas toward the edge of the wafer W, which may help reduce or eliminate a distribution fault that a CD at an edge of the wafer W is higher than a CD at the center of the wafer W. As the edge tuning gas supplier 125 supplies the edge tuning gas toward the edge of the wafer W, the density of plasma at an edge of a processing space may increase. This may help make the density of the plasma more uniform in the whole processing space, and a distribution fault in an etching process may be reduced or eliminated.

The focus ring 150 is seated on the lower electrode 130, and may have a form of a ring surrounding the edge of the wafer W. An inner portion of the focus ring 150 may be lower than an outer portion of the focus ring 150. The inner portion of the focus ring 150 may support an edge of the wafer W.

The focus ring 150 may be formed of, for example, silicon (Si), silicon carbide (SiC), carbon (C), or a combination thereof.

The focus ring 150 may cover at least a part of an edge of the lower electrode 130 so as to prevent penetration of a polymer compound, which may be generated in a process, into the lower electrode 130. Additionally, if high-frequency power is applied to the upper electrode 110 and/or the lower electrode 130, and thus, an electric field is formed, the focus ring 150 may expand an area in which the electric field is formed so that the whole wafer W is uniformly processed, and limit an area in which plasma is formed to within a certain area.

The edge ring 160 is arranged below the focus ring 150, and may support the focus ring 150.

The edge ring 160 may include the first bodies 161, which are separate from each other. The first bodies 161 may be radially arranged and separate from each other with a same space therebetween. In the drawing, eight first bodies 161 are included in the edge ring 160. The number of first bodies 161 may be less than, equal to, or greater than eight.

The first bodies 161 may be formed of a material having excellent heat conductivity. The heaters 170 may be installed in the first bodies 161. The first bodies 161 may be formed of, for example, metal having excellent heat conductivity, for example, aluminum.

The heaters 170 configured to adjust a temperature of the edge ring 160 may be installed in the edge ring 160. At least one heater 170 may be installed in each of the first bodies 161. As the heaters 170 are driven, a temperature of the first bodies 161 changes. As heat is exchanged between the focus ring 150 and the first bodies 161, a temperature of the focus ring 150 changes.

According to one or more embodiments, the heaters 170 may be heaters using a Joule heating method performed by heating the first bodies 161 by using heat generated when current flows through a conductor.

The heater controller 180 may separately control driving of the heaters 170. A temperature may locally increase at a part of the focus ring 150 which contacts the heaters 170 that are driven, and a temperature may decrease at another part of the focus ring 150 which contacts the heaters 170 that are not driven. The heater controller 180 may include a power source 181 for a heater, and a wiring 183 connecting the power source 181 for a heater to the heaters 170 included in the first bodies 161.

The heater controller 180 may separately control driving of the heaters 170. Thus, temperatures of the first bodies 161 that are separate from each other may be separately controlled and a temperature of the focus ring 150 may be locally controlled. For example, as shown in FIGS. 2 and 3, in the case that the edge ring 160 includes eight first bodies 161, the focus ring 150 may have eight temperature areas that are separately controlled.

FIG. 3 illustrates an example of a distribution map of the wafer W, in which an asymmetrical distribution fault has occurred. Here, an area of the wafer W, in which a small CD is measured, is shown bright in the distribution map, and another area of the wafer W, in which a larger CD is measured, is shown dark in the distribution map. If an asymmetrical distribution fault occurs, even if a distance from an area to a center of the wafer W is similar to that from another area to the center of the wafer W, a CD at the area may be different from a CD at the other area by a certain range of values or more.

If an asymmetrical distribution fault occurs, distribution at an edge of the wafer W may be non-uniform. Polymer deposited on an inner wall of the process chamber 101 or a component of the process chamber 101 may fall and be accumulated on a particular part of the wafer W. The polymer may deteriorate etching at the particular part of the wafer W. Thus, a distribution fault may occur at the edge of the wafer W.

Without being bound by theory, it is believed that, as a temperature of the focus ring 150 decreases, the polymer tends to move towards the focus ring 150 instead of an edge of the wafer W. Accordingly, the heater controller 180 controls the heaters 170, so that a temperature of an area of the focus ring 150, adjacent to an area of an edge of the wafer W in which a small CD is measured, locally increases. The heater controller 180 also controls the heaters 170 so that a temperature of another area of the focus ring 150, adjacent to another area of the edge of the wafer W in which a great CD is measured, locally decreases. Thus, a distribution fault at an edge of the wafer W may be reduced or eliminated.

For example, in the example illustrated in FIG. 3, the heater controller 180 obstructs current flow to heaters 170 respectively included in two first bodies 161 adjacent to a first edge area A1, in which a great CD is measured, of an edge of the wafer W, so as to resolve an asymmetrical distribution fault shown in FIG. 3. Thus, a temperature of an area of the focus ring 150, adjacent to the first edge area A1, may locally decrease. Additionally, the heater controller 180 may supply current to heaters 170 respectively included in other first bodies 161, so that a temperature of another area of the focus ring 150 may locally increase.

According to the present example embodiment, the first bodies 161 are arranged to be separate from each other. Thus, if a first body 161 is heated by driving the heater 170, an unintentional increase in a temperature of other first bodies 161 near the heated first body 161 may be prevented. Thus, according to the present example embodiment, the plasma processing apparatus 100 may effectively control a local temperature of the focus ring 150.

FIG. 4 is a schematic diagram of a configuration of the first bodies 161 of the edge ring 160 included in the plasma processing apparatus 100, and a heater controller 180a configured to control driving of heaters 170 included in the first bodies 161 according to an example embodiment.

Referring to FIGS. 1 and 4, the heater controller 180a may include the power source 181 for a heater, the wiring 183 connecting the power source 181 for a heater to the heaters 170 included in the first bodies 161, and a power distributor 185 for a heater which is configured to adjust current supplied to the heaters 170 by using variable resistance. For example, the power distributor 185 for a heater may adjust a temperature of the first bodies 161 by adjusting the amount of current supplied to the heaters 170, and locally adjust a temperature of the focus ring 150.

If a temperature of the focus ring 150 is to be further locally controlled, the first bodies 161 and the heaters 170 included in the first bodies 161 may be configured so that the number of first bodies 161 and the number of heaters 170 increase. Even if the number of heaters 170 increases, current supplied to the heaters 170 may be easily distributed by using the power distributor 185 for a heater. Thus, each heater 170 may be simply controlled.

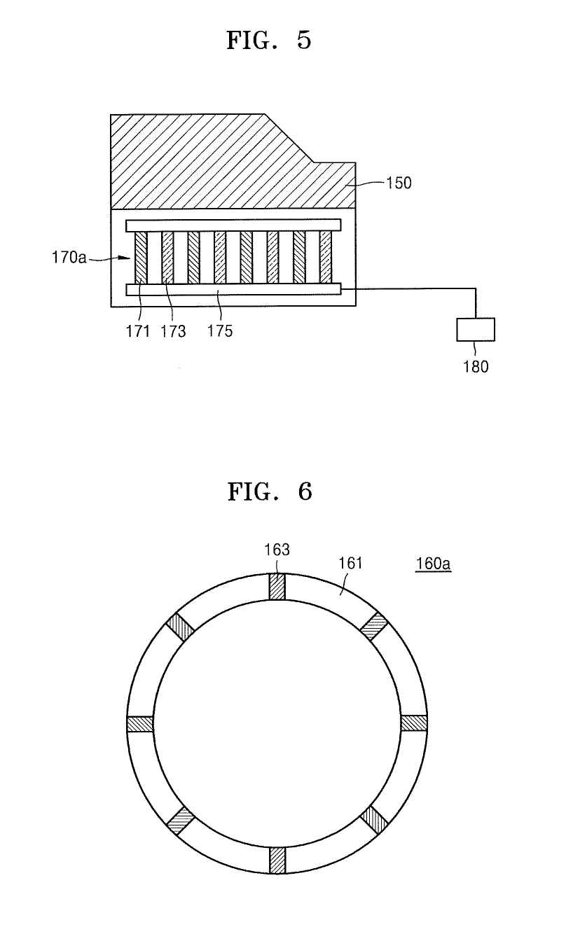

FIG. 5 is a schematic cross-sectional view of a heater 170a included in the plasma processing apparatus 100 according to an example embodiment.

Referring to FIG. 5, a heater using a thermoelectric module method of heating the first bodies 161 by using a thermoelectric device may be used as the heater 170a. The thermoelectric device may be a Peltier device that includes a first-type thermoelectric material 171 and a second-type thermoelectric material 173, which are different from each other, and a connection plate 175 electrically connecting the first-type thermoelectric material 171 to the second-type thermoelectric material 173. The thermoelectric device may heat or cool the first bodies 161, by using the Peltier effect of converting electrical energy into heat energy.

The heaters 170a using the thermoelectric module method may cool a part of the first bodies 161 to a temperature lower than an ambient temperature and precisely control a temperature of the first bodies 161. Accordingly, the heaters 170a using the thermoelectric module method may be used to precisely control a local temperature of the focus ring 150.

FIG. 6 is a schematic plan view of an edge ring 160a included in the plasma processing apparatus 100 according to an example embodiment.

Referring to FIG. 6, the edge ring 160a may include the first bodies 161 radially arranged and separate from each other, and second bodies 163 arranged between the first bodies 161. The second bodies 163 may be arranged between the first bodies 161 that neighbor each other. The first bodies 161 may be connected to each other via the second bodies 163. The edge ring 160a that includes the first bodies 161 and the second bodies 163 may have a form of a ring in which the first bodies 161 and the second bodies 163 are consecutively connected to each other.

The first bodies 161 may include a material having excellent heat conductivity, and a temperature of the first bodies 161 may be adjusted by using the heaters 170. The second bodies 163 may include an insulating material so that heat is limitedly exchanged between the first bodies 161. The second bodies 163 may be formed of an insulating material, and thus, may reduce heat delivery between the first bodies 161 that neighbor each other. In the present example embodiment, the second bodies 163 are arranged so that the edge ring 160a has a form of a ring in which the first bodies 161 and the second bodies 163 are consecutively connected to each other. Thus, the focus ring 150 located on the edge ring 160a may be stably supported.

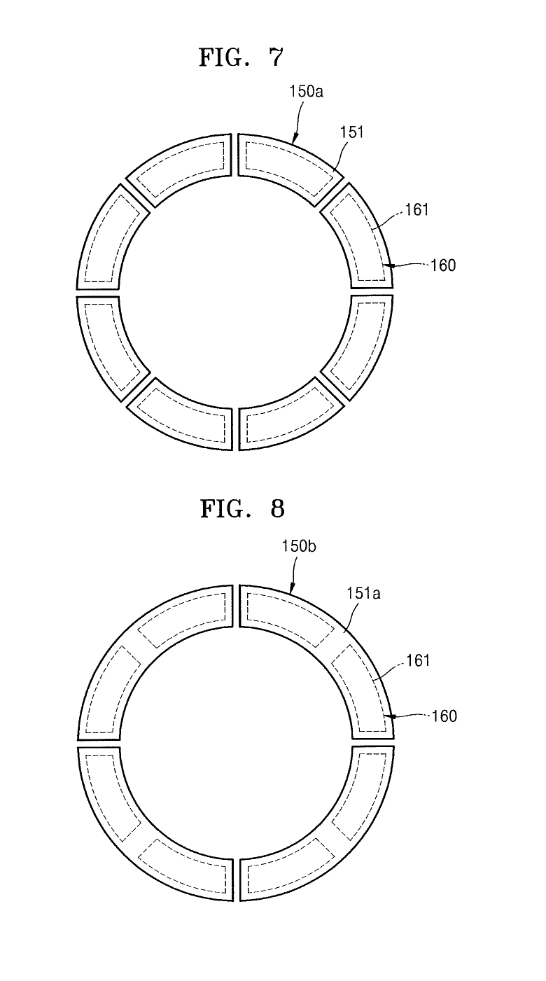

FIG. 7 is a plan view of a focus ring 150a and an edge ring 160 included in the plasma processing apparatus 100 according to an example embodiment.

Referring to FIG. 7, the focus ring 150a may include a plurality of focus ring bodies 151 arranged to be separate from each other with a same space therebetween. The focus ring 150a may have a form of a ring in which the focus ring bodies 151 are non-consecutively connected to each other.

The number of focus ring bodies 151 may respectively correspond to the number of first bodies 161 included in the edge ring 160. Each of the focus ring bodies 151 may be arranged to correspond to a first body 161 arranged below each of the focus ring bodies 151. In an example embodiment, eight focus ring bodies 151 and eight first bodies 161 are present. In various embodiments, fewer than eight or more than eight focus ring bodies 151 and/or first bodies 161 may be provided.

A length of the focus ring bodies 151 in a circumferential direction may be greater than a length of the first bodies 161 in a circumferential direction. The first bodies 161 may not be exposed between first focus ring bodies 151 that neighbor each other.

According to one or more embodiments, as shown in FIG. 6, the edge ring 160 may further include the second bodies 163 that are arranged between the first bodies 161 and formed of an insulating material. In this case, at least a part of the second bodies 163 may be exposed between the focus ring bodies 151.

In the present example embodiment, the focus ring bodies 151 are arranged to be physically separate from each other. Thus, heat delivery between the focus ring bodies 151 may be reduced and a local temperature of the focus ring 150 may be effectively controlled.

FIG. 8 is a plan view of a focus ring 150b and the edge ring 160 included in the plasma processing apparatus 100 according to an example embodiment.

Referring to FIG. 8, the focus ring 150b includes a plurality of focus ring bodies 151a that are separate from each other with a certain space therebetween. The focus ring 150b may be generally identical to the focus ring 150a described with reference to FIG. 7, except that the number of focus ring bodies 151a is less than the number of first bodies 161. Hereinafter, a description provided with reference to FIG. 7 will not be repeated or will be briefly provided.

The focus ring 150b may include a plurality of the focus ring bodies 151a that are separate from each other with a certain space therebetween. The number of focus ring bodies 151a may be less than the number of first bodies 161 of the edge ring 160. The focus ring bodies 151a may be radially arranged and separate from each other with a same space therebetween, and have a form of a ring in which the focus ring bodies 151a are non-consecutively connected to each other.

At least two first bodies 161 may be arranged to overlap with a focus ring body 151a in a longitudinal direction, and the first bodies 161 may not be exposed between first focus ring bodies 151a neighboring each other.

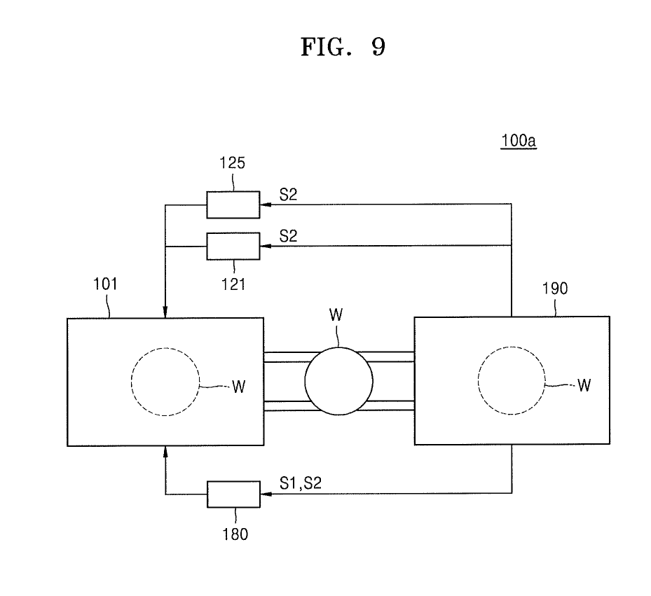

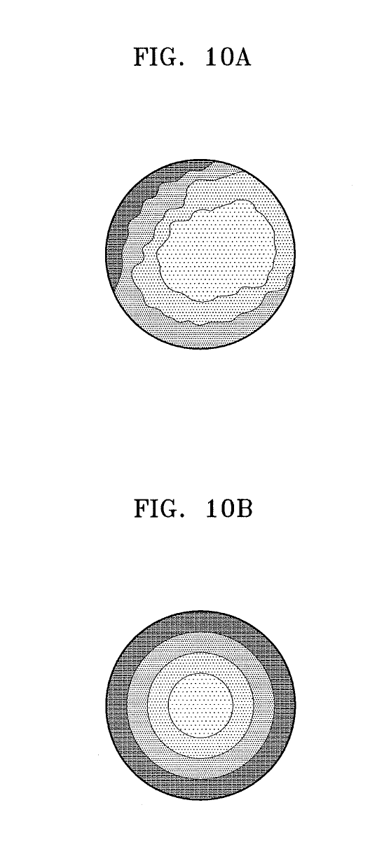

FIG. 9 is a schematic block diagram of a plasma processing apparatus 100a according to an example embodiment. FIGS. 10A and 10B are schematic distribution maps of the wafer W, which are generated by using a test apparatus 190 shown in FIG. 9.

The plasma processing apparatus 100a, shown in FIG. 9, may be generally identical to the plasma processing apparatus 100 described with reference to FIGS. 1-8 or elements of the plasma processing apparatus 100a may be generally identical to elements of the plasma processing apparatus 100, except that the plasma processing apparatus 100a further includes the test apparatus 190.

Referring to FIGS. 1, 9, 10a, and 10b, after the wafer W undergoes a plasma processing process, the test apparatus 190 may receive the wafer W from the process chamber 101. Then, the test apparatus 190 may measure a CD on a surface of the wafer W, for example, by testing a micro-pattern of the wafer W supplied from the process chamber 100. The test apparatus 190 may include an optical element for measuring a CD at a micro-pattern formed on the surface of the wafer W, and an image processor for processing the measured CD.

The test apparatus 190 may evaluate uniformity of a plasma processing process performed in the process chamber 101, by measuring a CD at the wafer W. Additionally, the test apparatus 190 may output a feedback signal for resolving a problem in the plasma processing process performed in the process chamber 101.

FIGS. 10A and 10B respectively illustrate a case when a CD measured with respect to the wafer W indicates an asymmetrical distribution fault and a case when a CD measured with respect to the wafer W indicates a concentric distribution fault.

Here, an asymmetric distribution fault may refer to a case when a CD at an area of the wafer W is different from a CD at another area of the wafer W by a certain range of values even when a distance between the area and a center of the wafer W is similar to a distance between the other area and the center of the wafer W. As shown in FIG. 10A, if an asymmetric distribution fault occurs, a CD at an edge of the wafer W is shown to be non-uniform.

Additionally, a concentric distribution fault may refer to a case when, if a distance between an area and a center of the wafer W is similar to a distance between another area and the center of the wafer W, a CD at the area of the wafer W is similar to a CD at the other area of the wafer W. For example, as shown in FIG. 10B, if a concentric distribution fault occurs, a CD at an area of the wafer W may be great when the area is far away from a center of the wafer W or adjacent to an edge of the wafer W. In other words, generally, the density of plasma may be lower at an edge of a processing space than at a center of the processing space. Accordingly, a CD at an edge of the wafer W may be greater than a CD at a center of the wafer W.

According to one or more embodiments, the test apparatus 190 may apply a first feedback signal S1 to the heater controller 180 so as to resolve the asymmetric distribution fault shown in FIG. 10A. According to the first feedback signal S1, the heater controller 180 may control the heaters 170 so that a temperature of an area of the focus ring 150, which is adjacent to an edge of the wafer W at which a great CD is measured, locally decreases, or control the heaters 170 so that a temperature of an area of the focus ring 150, which is adjacent to an edge of the wafer W at which a small CD is measured, locally increases.

Then, an amount of polymer accumulated at an area, in which a temperature of the focus ring 150 locally decreases, may increase, such that an area of an edge of the wafer W adjacent to the area where a temperature of the focus ring 150 locally decreases is affected little by the polymer, and thus, an etching rate may increase. On the other hand, a reduced amount of polymer may accumulate at an area in which a temperature of the focus ring 150 locally increases, such that an etching rate at an area of an edge of the wafer W adjacent to the area, in which a temperature of the focus ring 150 locally increases, decreases due to the increasing polymer. Resultantly, the asymmetric distribution fault shown in FIG. 10 may be resolved, and a distribution at an edge of the wafer W may become more uniform.

Additionally, according to one or more embodiments, the test apparatus 190 may apply a second feedback signal S2 to the heater controller 180, the gas splitter 121, and/or the edge tuning gas supplier 125, so as to reduce or eliminate the concentric distribution fault shown in FIG. 10B.

According to the second feedback signal S2, the heater controller 180 may control all the heaters 170 at a same time or may not drive any of the heaters 170 so that temperatures with respect to the whole focus ring 150 may increase or decrease at a same time. For example, if a CD at an edge of the wafer W is great, current supplied to all the heaters 170 may be obstructed or decreased so that a temperature of the whole focus ring 150 decreases. As a temperature of the whole focus ring 150 decreases, an amount of polymer accumulated in the focus ring 150 may increase, and an amount of polymer accumulated at an edge of the wafer W may decrease. Accordingly, an etching rate at an edge of the wafer W may increase, and CD distribution at a center of the wafer W and an edge of the wafer W may become more uniform.

Additionally, the gas splitter 121 may adjust flow of process gas sprayed toward a center of the wafer W and flow of process gas sprayed toward an edge of the wafer W according to the second feedback signal S2. For example, if a CD at an edge of the wafer W is great, process gas may be distributed so that flow of process gas supplied toward the center of the wafer W decreases. Accordingly, the density of plasma at an edge of a processing space may increase, and thus, an etching rate at an edge of the wafer W increases and CD distribution at a center of the wafer W and at the edge of the wafer W may become uniform.

Further, the edge tuning gas supplier 125 may supply edge tuning gas toward an edge of the wafer W according to the second feedback signal S2. For example, if a CD at an edge of the wafer W is great, the edge tuning gas supplier 125 may adjust an amount of edge tuning gas supplied to an edge of a processing space. As the edge tuning gas supplied to the edge of the processing space is excited, the density of plasma at an edge of the processing space may increase. Thus, as an etching rate at an edge of the wafer W increases, CD distribution at the center and the edge of the wafer W may become uniform.

According to embodiments, when the wafer W is tested by the test apparatus 190, if an asymmetric distribution fault occurs in the wafer W, the plasma processing apparatus 100a may reduce or eliminate the asymmetric distribution fault at an edge of the wafer W by locally controlling a temperature of the focus ring 150. Additionally, the plasma processing apparatus 100a may reduce or eliminate a concentric distribution fault by performing at least one of control of flow of process gas by using the gas splitter 121, control of flow of edge tuning gas by using the edge tuning gas supplier 125, and control of a temperature of the whole focus ring 150. These controls may be performed so as to resolve a concentric distribution fault at a same time when, or sequentially before or after, a temperature of the focus ring 150 is locally controlled so as to reduce or eliminate an asymmetric distribution fault at the edge of the wafer W.

By way of summation and review, as a semiconductor product is miniaturized and highly integrated, the effect of a distribution fault on characteristics of a semiconductor product in an etching process may increase.

As described above, embodiments are directed to a plasma processing apparatus configured to reduce or eliminate a distribution fault in an etching process.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A plasma processing apparatus, comprising:
a process chamber providing a space for plasma processing;
a lower electrode that is in the process chamber, a surface of the lower electrode being for mounting a wafer thereon;
an upper electrode that is in the process chamber and faces the lower electrode;
a gas supplier configured to supply process gas between the upper electrode and the lower electrode;
a focus ring arranged on the lower electrode to surround an edge of the wafer mounted on the lower electrode;
an edge ring arranged below the focus ring and including first bodies that are separate from each other with a space therebetween;
a plurality of heaters installed in the first bodies; and
a heater controller configured to separately control driving of each of the heaters.

2. The plasma processing apparatus as claimed in claim 1, wherein the edge ring further includes second bodies that are arranged between the first bodies neighboring each other, the second bodies including an insulating material.

3. The plasma processing apparatus as claimed in claim 1, wherein the first bodies are radially arranged and separate from each other with a same space therebetween.

4. The plasma processing apparatus as claimed in claim 1, wherein the focus ring includes a plurality of focus ring bodies that are separate from each other.

5. The plasma processing apparatus as claimed in claim 4, wherein a number of the focus ring bodies corresponds to a number of the first bodies.

6. The plasma processing apparatus as claimed in claim 4, wherein a number of the focus ring bodies is less than a number of the first bodies.

7. The plasma processing apparatus as claimed in claim 1, wherein the heater controller separately adjusts temperatures of the first bodies by providing current to each of the plurality of heaters or obstructing current to each of the heaters.

8. The plasma processing apparatus as claimed in claim 1, wherein the heater controller separately adjusts temperatures of the first bodies by adjusting current supplied to each of the heaters by using variable resistance.

9. The plasma processing apparatus as claimed in claim 1, wherein the heaters include thermoelectric devices arranged inside the first bodies.

10. The plasma processing apparatus as claimed in claim 1, further comprising a test apparatus configured to receive the wafer from the process chamber and test the wafer after a plasma processing process is performed on the wafer, and apply a feedback signal to the heater controller.

11. A plasma processing apparatus, comprising:
a process chamber providing a space for plasma processing;
a lower electrode that is in the process chamber, a surface of the lower electrode being for mounting a wafer thereon;
an upper electrode that is in the process chamber and faces the lower electrode;
a gas supplier configured to supply processing gas to a processing space between the upper electrode and the lower electrode;
a focus ring arranged on the lower electrode to surround an edge of the wafer mounted on the lower electrode;
an edge ring arranged below the focus ring and including first bodies that are separate from each other with a space therebetween;
a plurality of heaters installed in the first bodies;
a heater controller configured to separately control driving of each of the heaters; and
a test apparatus configured to receive the wafer from the process chamber and test the wafer after an etching process is performed on the wafer, and apply a first feedback signal to the heater controller if a result of the testing shows that an asymmetric distribution fault has occurred in the tested wafer,
wherein the heater controller drives the heaters so that some of the first bodies are heated according to the first feedback signal.

12. The plasma processing apparatus as claimed in claim 11, wherein:
the test apparatus applies a second feedback signal to the heater controller if a concentric distribution fault has occurred in the tested wafer, and
the heater controller drives all of the heaters or does not drive any of the plurality of heaters according to the second feedback signal.

13. The plasma processing apparatus as claimed in claim 11, further comprising a gas splitter installed between the gas supplier and the upper electrode, and configured to distribute process gas to a center and an edge of the wafer mounted on the lower electrode when the process gas is supplied toward the center and the edge of the wafer,
wherein the test apparatus applies a second feedback signal to the gas splitter if a concentric distribution fault has occurred in the tested wafer, and
the gas splitter distributes flow of process gas supplied to the center and the edge of the wafer mounted on the lower electrode at a ratio according to the second feedback signal.

14. The plasma processing apparatus as claimed in claim 11, further comprising an edge tuning gas supplier configured to supply edge tuning gas toward an edge of the wafer mounted on the lower electrode, wherein:
the test apparatus applies a second feedback signal to the edge tuning gas supplier if a result of the testing shows that a concentric distribution fault has occurred in the tested wafer, and
the edge tuning gas supplier adjusts flow of edge tuning gas supplied toward an edge of the wafer mounted on the lower electrode according to the second feedback signal.

15. The plasma processing apparatus as claimed in claim 11, wherein the focus ring includes a plurality of focus ring bodies that are separate from each other and are provided in correspondence with a number of the first bodies.

16. An edge ring for a plasma processing apparatus, the edge ring comprising:
a plurality of arc-shaped sections, the arc-shaped sections being provided in a number sufficient to define a circle; and
electrically-driven thermal control elements contacting the arc-shaped sections, each arc-shaped section having at least one thermal control element in contact therewith.

17. The edge ring as claimed in claim 16, wherein the thermal control elements are thermoelectric devices.

18. The edge ring as claimed in claim 17, wherein the thermoelectric devices have opposing heating and cooling sides, the heating and cooling sides being stacked in a thickness direction of the edge ring.

19. The edge ring as claimed in claim 17, wherein the thermoelectric devices are independently controllable.

20. The edge ring as claimed in claim 16, wherein the arc-shaped sections are connected by thermally insulating material to form an unbroken ring having an outer diameter that is at least as great as that of a wafer for which the edge ring is provided.
